(19) United States
(12) Patent Application Publication
(10) Pub. No.: US 2009/0146264 A1
(43) Pub. Date: Jun. 11, 2009

(54) THIN FILM TRANSISTOR ON SODA LIME GLASS WITH BARRIER LAYER

(75) Inventors: YA-TANG YANG, Cupertino, CA (US); BEOM SOO PARK, San Jose, CA (US); TAE K. WON, San Jose, CA (US); SOO YOUNG CHOI, Fremont, CA (US); JOHN M. WHITE, Hayward, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/277,921

(22) Filed: Nov. 25, 2008

Related U.S. Application Data
(60) Provisional application No. 60/991,685, filed on Nov. 30, 2007.

(51) Int. Cl. H01L 29/06; H01L 21/336; H01L 21/31

(52) U.S. Cl. 257/632; 438/158; 438/792; 257/E29.02; 257/E21.414; 257/E21.24

(57) ABSTRACT

The present invention generally comprises a low cost TFT and a method of manufacturing a TFT. For TFTs, soda lime glass would be an attractive alternative to non-alkali glass, but a soda lime glass substrate will permit sodium to diffuse into the active layer and degrade the performance of the TFT. Substrates comprising a polyimide, because they are flexible, would also be attractive to utilize instead of non-alkali glass substrates, but the plastic substrates permit carbon to diffuse into the active layer. By depositing a silicon rich barrier layer over the soda lime glass substrate or substrate comprising a polyimide, both sodium and carbon diffusion may be reduced. Thus, a lower cost TFT may be produced with a soda lime glass substrate or a substrate comprising a polyimide as compared to a non-alkali glass substrate.

### CROSS-REFERENCE TO RELATED APPLICATIONS

This application claims benefit of U.S. Provisional Patent Application Ser. No. 60/991,685 (APPM/12656L), filed Nov. 30, 2007, which is herein incorporated by reference.

### BACKGROUND OF THE INVENTION

1. Field of the Invention

Embodiments of the present invention generally relate to a thin film transistor (TFT) formed over either a soda lime glass substrate or a polyimide containing substrate.

2. Description of the Related Art

Liquid crystal displays (LCDs) may be formed on high performance non-alkali glass developed specifically for LCD applications. The LCD comprises a TFT formed over a non-alkali glass substrate. Non-alkali glass substrates have few contaminants that may diffuse into the TFT and thus make non-alkali glass substrates attractive for TFT fabrication. However, non-alkali glass is quite expensive. Soda lime glass has been proposed as an alternative to non-alkali glass substrates, but soda lime glass has a significant amount of sodium that easily diffuses into the active layer of the TFT which will degrade the TFT device.

Therefore, there is a need in the art for a TFT formed on a substrate that is lower in cost than non-alkali-glass substrates. There is also a need in the art for the TFT formed on the lower cost substrate to not have contaminants diffuse into the active layer from the substrate.

### SUMMARY OF THE INVENTION

The present invention generally comprises a low cost TFT and a method for making the TFT. In one embodiment, a thin film transistor comprises a soda lime glass substrate and a silicon rich silicon nitride barrier layer disposed over the substrate, the barrier layer having a silicon:nitrogen ratio greater than 0.83:1.0.

In another embodiment, a thin film transistor comprises a substrate comprising a polyimide and a silicon rich silicon nitride barrier layer disposed over the substrate, the barrier layer having a silicon:nitrogen ratio greater than 0.83:1.0.

In another embodiment, a thin film transistor formation method comprises depositing a silicon rich silicon nitride barrier layer over a soda lime glass substrate, the barrier layer having a silicon:nitrogen ratio greater than 0.83:1.0, depositing a metal gate layer over the barrier layer, depositing a gate dielectric layer over the metal gate layer, depositing an active layer over the gate dielectric layer, depositing a source-drain region over the active layer, and depositing a passivation layer over the source-drain region.

In another embodiment, a thin film transistor formation method comprises depositing a silicon rich silicon nitride barrier layer over a substrate comprising a polyimide, the barrier layer having a silicon:nitrogen ratio greater than 0.83:1.0, depositing a metal gate layer over the barrier layer, depositing a gate dielectric layer over the metal gate layer, depositing an active layer over the gate dielectric layer, depositing a source-drain region over the active layer, and depositing a passivation layer over the source-drain region.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of a PECVD apparatus according to one embodiment of the invention.

FIG. 2 is a schematic drawing of a TFT structure.

FIGS. 3A and 3B show a comparison of the level of sodium contamination of the TFT structure for a soda lime glass substrate with a barrier layer (FIG. 3A) and without a barrier layer (FIG. 3B).

FIGS. 4A and 4B show a comparison of the level of carbon contamination of the TFT structure for a Kapton™ substrate with a barrier layer (FIG. 4A) and without a barrier layer (FIG. 4B).

FIGS. 5A and 5B are secondary ion mass spectrometry charts showing the sodium and carbon density as measured in the middle of the barrier layer.

FIGS. 6A and 6B are secondary ion mass spectrometry charts showing the sodium and carbon density as measured in the middle of the barrier layer.

FIGS. 7A and 7B are secondary ion mass spectrometry charts showing the sodium and carbon density as measured in the middle of the barrier layer.

FIGS. 8A and 8B are secondary ion mass spectrometry charts showing the sodium and carbon density as measured in the middle of the barrier layer.

FIGS. 9A and 9B are secondary ion mass spectrometry charts showing the sodium and carbon density as measured in the middle of the barrier layer.

FIGS. 10A and 10B are secondary ion mass spectrometry charts showing the sodium and carbon density as measured in the middle of the gate dielectric layer.

FIGS. 11A and 11B are secondary ion mass spectrometry charts showing the sodium and carbon density as measured in the middle of the gate dielectric layer.

FIGS. 12A and 12B are secondary ion mass spectrometry charts showing the sodium and carbon density as measured in the middle of the gate dielectric layer.

FIG. 13 is a secondary ion mass spectrometry chart showing the carbon density as measured in the middle of the barrier layer.

FIG. 14 is a secondary ion mass spectrometry chart showing the carbon density as measured in the middle of the gate dielectric layer.

FIG. 15 is a secondary ion mass spectrometry chart showing the carbon density as measured in the middle of the gate dielectric layer.

FIG. 16 is a secondary ion mass spectrometry chart showing the carbon density as measured in the middle of the barrier layer.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally comprises a low cost TFT and a method of manufacturing a TFT. For TFTs, soda lime glass would be an attractive alternative to non-alkali glass, but a soda lime glass substrate will permit sodium to diffuse into the active layer and degrade the performance of the TFT. Substrates comprising a polyimide, because they are flexible, would also be attractive to utilize instead of non-alkali glass substrates, but the plastic substrates permit carbon to diffuse into the active layer. By depositing a silicon rich barrier layer having a silicon:nitrogen ratio greater than 1.0:1.2 over the soda lime glass substrate or substrate comprising a polyimide, both sodium and carbon diffusion may be reduced. Thus, a lower cost TFT may be produced with a soda lime glass substrate or a substrate comprising a polyimide as compared to a non-alkali glass substrate.

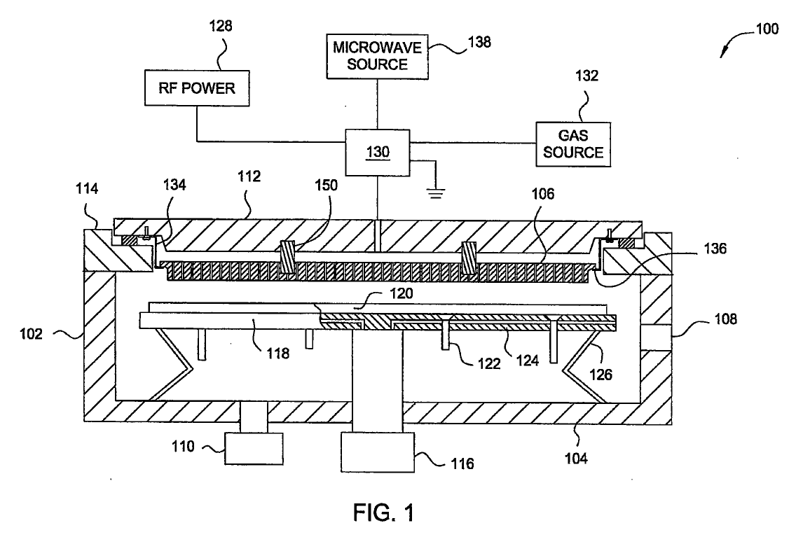

FIG. 1 is a cross sectional view of a PECVD apparatus according to one embodiment of the invention. The apparatus includes a chamber 100 in which one or more films may be deposited onto a substrate 120. One suitable PECVD apparatus which may be used is available from AKT America, Inc., a subsidiary of Applied Materials, Inc., located in Santa Clara, Calif. While the description below will be made in reference to a PECVD apparatus, it is to be understood that the invention is equally applicable to other processing chambers as well, including those made by other manufacturers.

The chamber 100 generally includes walls 102, a bottom 104, a showerhead 106, and susceptor 118 which define a process volume. The process volume is accessed through a slit valve opening 108 such that the substrate 120 may be transferred in and out of the chamber 100. The susceptor 118 may be coupled to an actuator 116 to raise and lower the susceptor 118. Lift pins 122 are moveably disposed through the susceptor 118 to support a substrate 120 prior to placement onto the susceptor 118 and after removal from the susceptor 118. The susceptor 118 may also include heating and/or cooling elements 124 to maintain the susceptor 118 at a desired temperature. The susceptor 118 may also include grounding straps 126 to provide RF grounding at the periphery of the susceptor 118.

The showerhead 106 is coupled to a backing plate 112 by a fastening mechanism 150. The showerhead 106 may be coupled to the backing plate 112 by one or more coupling supports 150 to help prevent sag and/or control the straightness/curvature of the showerhead 106. In one embodiment, twelve coupling supports 150 may be used to couple the showerhead 106 to the backing plate 112. The coupling supports 150 may include a fastening mechanism such as a nut and bolt assembly. In one embodiment, the nut and bolt assembly may be made with an electrically insulating material. In another embodiment, the bolt may be made of a metal and surrounded by an electrically insulating material. In still another embodiment, the showerhead 106 may be threaded to receive the bolt. In yet another embodiment, the nut may be formed of an electrically insulating material. The electrically insulating material helps to prevent the coupling supports 150 from becoming electrically coupled to any plasma that may be present in the chamber 100. Additionally and/or alternatively, a center coupling mechanism may be present to couple the backing plate 112 to the showerhead 106. The center coupling mechanism may surround a backing plate support ring (not shown) and be suspended from a bridge assembly (not shown). The showerhead 106 may additionally be coupled to the backing plate 112 by a bracket 134. The bracket 134 may have a ledge 136 upon which the showerhead 106 may rest. The backing plate 112 may rest on a ledge 114 coupled with the chamber walls 102 to seal the chamber 100.

A gas source 132 is coupled to the backing plate 112 to provide both processing gas and cleaning gas through gas passages in the showerhead 106 to the substrate 120. The processing gases travel through a remote plasma source/RF choke unit 130. A vacuum pump 110 is coupled to the chamber 100 at a location below the susceptor 118 to maintain the process volume 106 at a predetermined pressure. A RF power source 128 is coupled to the backing plate 112 and/or to the showerhead 106 to provide a RF current to the showerhead 106. The RF current creates an electric field between the showerhead 106 and the susceptor 118 so that a plasma may be generated from the gases between the showerhead 106 and the susceptor 118. Various frequencies may be used, such as a frequency between about 0.3 MHz and about 200 MHz. In one embodiment, the RF current is provided at a frequency of 13.56 MHz.

Between processing substrates, a cleaning gas may be provided to the remote plasma source/RF choke unit 130 so that a remote plasma is generated and provided to clean the chamber 100 components. A microwave current from a microwave source 138 coupled to the remote plasma source/RF choke 130 may ignite the plasma. It is to be understood that sources other than microwave sources may be used. Additionally, while the remote plasma source/RF choke 130 is shown coupled to ground, it is to be understood that the RF current returns to the source driving it which is sometimes referred to as “RF grounding” in the art. The cleaning gas may be further excited by the RF power source 128 provided to the showerhead 106. Suitable cleaning gases include by are not limited to NF₃, F₂, and SF₆. The spacing between the top surface of the substrate 120 and the showerhead 106 may be between about 400 mil and about 1,200 mil. In one embodiment, the spacing may be between about 400 mil and about 800 mil.

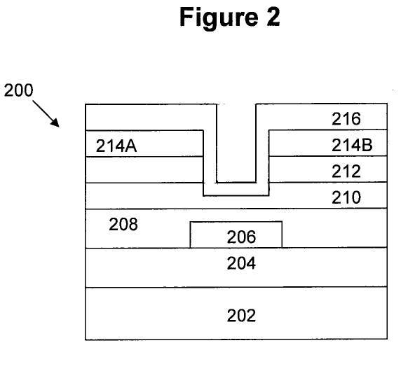

PECVD may be used to deposit various layers of a TFT. FIG. 2 is a schematic drawing of a TFT structure 200 according to one embodiment of the invention. The TFT structure comprises a substrate 202. In one embodiment, the substrate may comprise soda lime glass. In another embodiment, the substrate may comprise a plastic. In one embodiment, the plastic may be a polyimide. In another embodiment, the substrate may comprise poly(4,4′-oxydiphenylene-pyromellitimide).

When the substrate is soda lime glass, sodium, magnesium, calcium, and carbon may be present and diffuse into the active layer of the TFT. When the substrate is a plastic substrate, carbon, sodium, and calcium may be present and diffuse into the active layer of the TFT. The contaminants may degrade the TFT device performance or even cause the device to fail. To prevent diffusion of the contaminants into the active layer, a barrier layer 204 may be deposited over the substrate. The barrier layer 204 may comprise silicon nitride, a silicon oxynitride, silicon carbide, or silicon dioxide. Of course, multiple barrier layers 204 may be present in which a combination of the aforementioned barrier layers 204 are stacked over the substrate. Over the barrier layer 204, the metal gate 206, gate dielectric layer 208, active layer 210, doped active layer 212, source-drain region 214A, 214B, and passivation layer 216 may be deposited.

The barrier layer 204 may be deposited by introducing a substrate into a PECVD processing chamber and disposing the substrate onto a susceptor. The susceptor may be maintained at a temperature between about 180 degrees Celsius and about 210 degrees Celsius. For silicon nitride, a silicon precursor processing gas, a nitrogen precursor processing gas, nitrogen gas, and hydrogen gas may be introduced into the processing chamber. In one embodiment, the silicon precursor gas may comprise silane. In one embodiment, the nitrogen precursor gas may comprise ammonia.

The barrier layer 204 should be a silicon rich layer. By silicon rich it is to be understood to include more silicon is present than is necessary to produce silicon nitride Si₃N₄. Silicon rich silicon nitride films have a higher silicon content then standard silicon nitride films. In one embodiment, the ratio of silicon to nitrogen may be greater than about 0.80:1.0. In another embodiment, the ratio may be greater than about 0.83:1.0. In another embodiment, the ratio may be greater than about 0.85:1.0. Because of this higher silicon content, silicon rich silicon nitride films have an index of refraction that is higher than standard silicon nitride films. Standard silicon nitride films have an index of refraction of about 1.8 to 1.9. In contrast, silicon rich silicon nitride films have an index of refraction of about 1.95 or greater. In some embodiments, the barrier layer also has a higher SiH content than NH content. In other embodiments, the barrier layer may have a lower SiH content than NH content. The refractive index of the barrier layer 204 should be high. In one embodiment, the refractive index may be equal to or greater than about 1.900. In another embodiment, the refractive index may be between about 1.920 and about 1.940. The barrier layer 204 should also have a low wet etch rate. In one embodiment, the wet etch rate may be between about 3000 Angstroms/min to about 3200 Angstroms/min. In another embodiment, the wet etch rate may be between about 3100 Angstroms/min to about 3160 Angstroms/min. The barrier layer 204 may be deposited to a thickness between about 3500 Angstroms to about 4500 Angstroms. In one embodiment, the barrier layer 204 thickness may be between about 3750 Angstroms to about 4250 Angstroms. In another embodiment, the barrier layer 204 thickness may be between about 3900 Angstroms to about 4100 Angstroms. In another embodiment, the barrier layer 204 may have a thickness between about 0.9 microns and about 1.1 microns.

While discussed as a single barrier layer 204, a multi-layer barrier layer may be used. In situations where the barrier layer may be uneven when deposited, a second barrier layer may be deposited over the first barrier layer. The first barrier layer may be deposited to increase adhesion with the substrate 202. The first barrier layer may have a thickness of between about 0.05 to about 0.1 microns. The second barrier layer may then be deposited over the first barrier layer to a thickness between about 0.8 microns to about 1.0 microns. The first barrier layer and the second barrier layer may comprise the same materials. In another embodiment, the first barrier layer and the second barrier layer may comprise a silicon rich silicon nitride. In another embodiment, the first and second barrier layers may be different. For example, the silicon content of the barrier layers may be different.

Over the barrier layer 204, a metal gate layer 206 may be deposited and patterned. In one embodiment, the metal gate layer 206 may comprise chromium. The metal gate layer 206 may be deposited by sputtering. In one embodiment, the metal gate layer 206 may have a thickness between about 1000 Angstroms to about 2000 Angstroms. The metal gate layer 206 may be patterned by photolithography and a plasma etch.

A gate dielectric layer 208 may be deposited over the metal gate layer 206. The gate dielectric layer 208 may be deposited by PECVD. In one embodiment, the gate dielectric layer 208 may comprise silicon nitride. Over the gate dielectric layer, the active layer 210 may be deposited. In one embodiment, the active layer 210 may comprise amorphous silicon. The active layer 210 may be doped to form a doped active layer 212. In one embodiment, the doped active layer 212 may comprise n-doped amorphous silicon. In one embodiment, the gate dielectric layer 208, the active layer 210, and the doped active layer 212 may be deposited within the same processing chamber. It is to be understood that while amorphous silicon has been discussed as the active layer and doped active layer, other materials may be used as well. In particular, transparent conductive oxides such as zinc oxide may be used.

A source drain region may then be formed over the doped active layer 212. A metal layer may be sputter deposited over the doped active layer 212. In one embodiment, the metal layer may comprise chromium. Thereafter, the source drain regions may be formed by a two step photolithography method and plasma etch to define the active channel and source 214A and drain 214B regions of the TFT. A passivation layer 216 may then be deposited. In one embodiment, the passivation layer 216 may comprise silicon nitride.

Table I shows the output characteristics of an amorphous silicon TFT. The table shows the results for a TFT formed over a soda lime glass substrate having a silicon rich barrier layer, for a TFT formed over a soda lime glass substrate without a barrier layer, and for a TFT formed over a Corning glass substrate. The TFTs had a channel width of about 40 microns and a channel length of about 10 microns. A Corning glass substrate is a non-alkali glass substrate. As shown in Table I, a soda lime glass substrate that has a 1 micron barrier layer formed thereover has a saturation mobility, off current, on current, and subthreshold swing comparable to those for a non-alkali glass substrate. The saturation mobility, off current, on current, and subthreshold swing for the soda lime glass having a barrier layer are within the usable range for a production line.

TABLE I

| | | μₛₐₜ | Vth | Ioff | Ion | S |
|---|---|---|---|---|---|---|
| Substrate | Barrier | cm²/Vs | V | A | A | V/dec |
| Soda lime | 1 μm SiNx | 0.47 | 0.0 | 7.7 × 10⁻¹¹ | 2.4 × 10⁻⁶ | 1.0 |
| Soda lime | None | 0.42 | −3.1 | 2.9 × 10⁻⁹ | 3.7 × 10⁻⁶ | 2.9 |
| Corning | None | 0.59 | 0.0 | 5.7 × 10⁻¹⁰ | 4.0 × 10⁻⁶ | 1.6 |

The soda lime glass substrate without a barrier layer has a lower saturation mobility, high off current, and a subthreshold swing degradation that is caused by the sodium diffusion into the active layer. The high saturation swing can be attributed to degradation of the amorphous silicon network due to sodium contamination. The high off current is attributed to the ionic conduction from sodium embedded in the amorphous silicon layer. The negative threshold voltage shift, as compared to the soda lime glass substrate with a barrier layer, is attributed to the ionic charge of sodium.

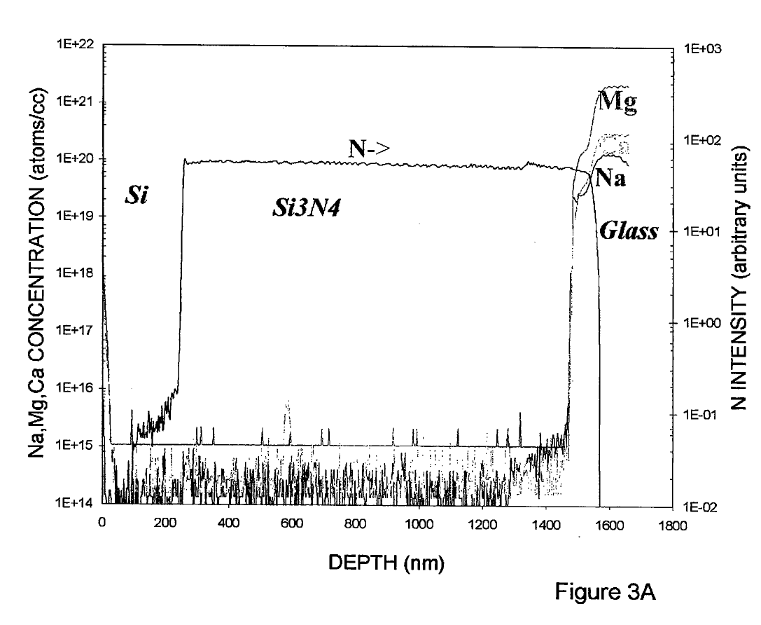

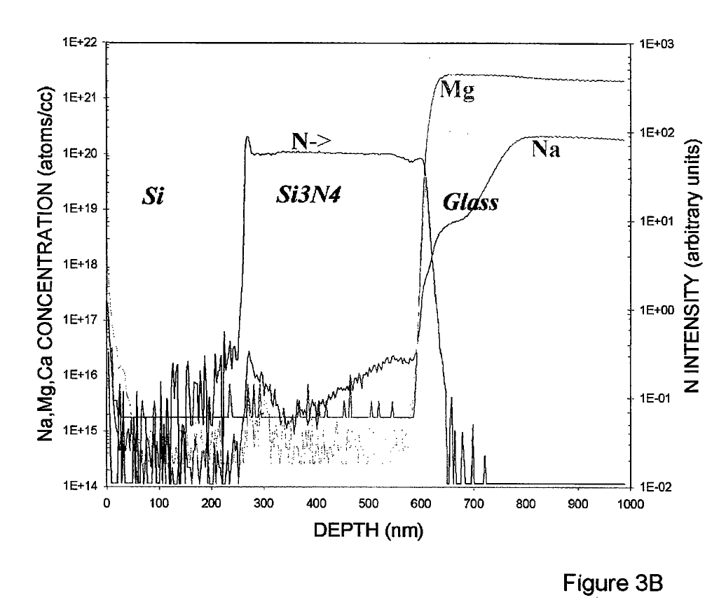

FIGS. 3A and 3B shows a comparison of the level of sodium contamination of the TFT structure for a soda lime glass substrate with a barrier layer (FIG. 3A) and without a barrier layer (FIG. 3B). As can be seen, when a barrier layer is present, the sodium concentration is much less than when no barrier layer is present. Specifically, when a barrier layer is present, the sodium concentration may remain below about 1×10¹⁵ atoms/cc for a distance of about 1200 nm from the interface of the gate dielectric layer and the amorphous silicon layer as measured by secondary ion mass spectrometry. However, when no barrier layer is present, the sodium concentration may be above about 1×10¹⁵ atoms/cc for the entire thickness of the gate dielectric layer as measured by secondary ion mass spectrometry.

Table II shows the output characteristics of an amorphous silicon TFT. The table shows the results for a TFT formed over a Kapton™ (i.e., poly(4,4′-oxydiphenylene-pyromellitimide)) substrate having a silicon rich barrier layer, for a TFT formed over a Kapton™ substrate without a barrier layer, for a TFT formed over a Corning glass substrate, and for a TFT formed over an oxidized silicon substrate. The TFTs had a channel width of about 40 microns and a channel length of about 10 microns. As shown in Table II, a Kapton™ substrate that has a 0.4 micron barrier layer formed thereover has a saturation mobility, off current, on current, and subthreshold swing comparable to those for a non-alkali glass substrate. The saturation mobility, off current, on current, and subthreshold swing for the soda lime glass having a barrier layer are within the usable range for a production line.

TABLE II

| | | μₛₐₜ | Vth | Ioff | Ion | S |
|---|---|---|---|---|---|---|
| Substrate | Barrier | cm²/Vs | V | A | A | V/dec |
| Kapton ™ E | 0.4 μm | 0.4 | −0.3 | 1.9 × 10⁻¹² | 2.1 × 10⁻⁶ | 0.6 |
| | SiNx | | | | | |
| Kapton ™ E | None | 0.29 | 2.2 | 2.3 × 10⁻⁸ | 1.2 × 10⁻⁶ | 1.5 |
| Corning | None | 0.59 | 0.0 | 5.7 × 10⁻¹⁰ | 4.0 × 10⁻⁶ | 1.6 |
| Oxidized Si | None | 0.57 | 0.0 | 6.1 × 10⁻¹¹ | 2.5 × 10⁻⁶ | 0.8 |

The Kapton™ substrate without a barrier layer has a lower saturation mobility, high off current, and a subthreshold swing degradation that is caused by the carbon diffusion into the active layer. The high saturation swing can be attributed to degradation of the amorphous silicon network due to carbon contamination. The high off current is attributed to the carbon assisted conduction in the amorphous silicon layer. The mobility degradation is attributed to degradation of the amorphous silicon network due to carbon contamination.

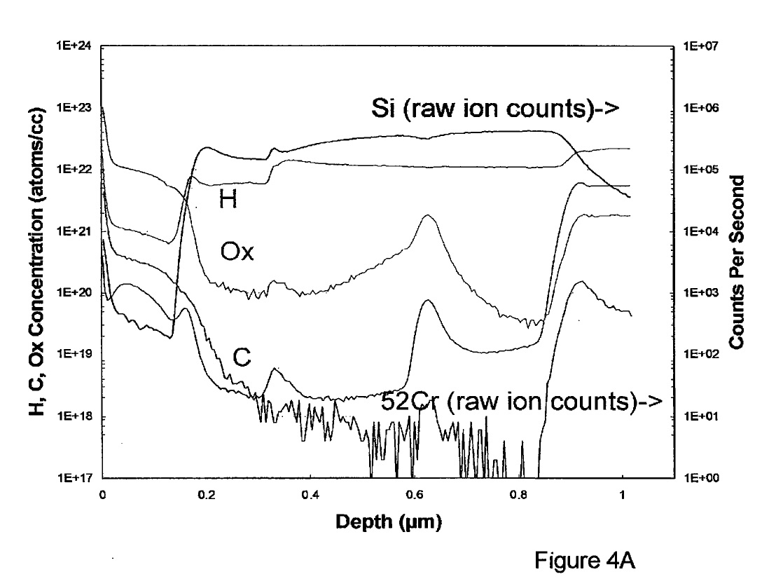

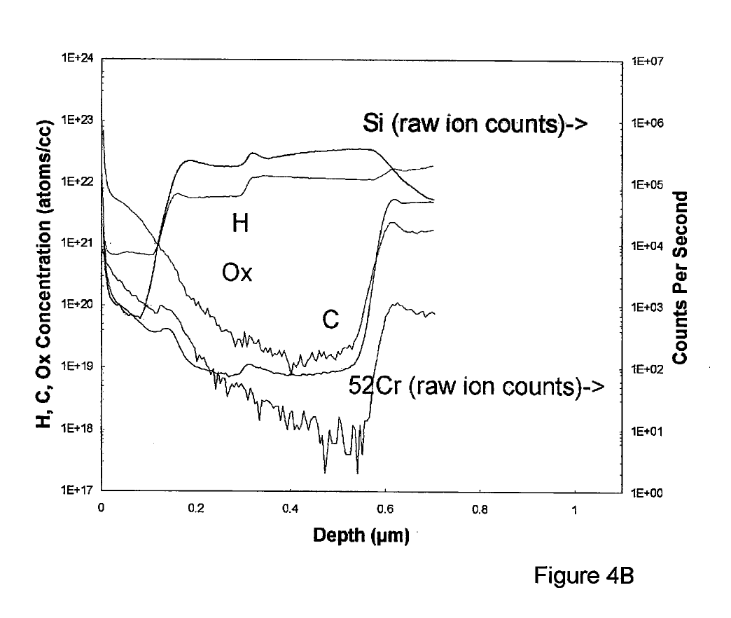

FIGS. 4A and 4B shows a comparison of the level of carbon contamination of the TFT structure for a Kapton™ substrate with a barrier layer (FIG. 4A) and without a barrier layer (FIG. 4B). As can be seen, when a barrier layer is present, the carbon concentration is much less than when no barrier layer is present. Specifically, when a barrier layer is present, the carbon concentration may remain below about 1×10¹⁹ atoms/cc for a distance of about 0.4 microns from the interface of the gate dielectric layer and the amorphous silicon layer as measured by secondary ion mass spectrometry. However, when no barrier layer is present, the carbon concentration may be above about 1×10¹⁹ atoms/cc for the entire thickness of the gate dielectric layer as measured by secondary ion mass spectrometry.

### EXAMPLES

TABLE III

| | | Refractive | Stress | SiH | N—H | WER |
|---|---|---|---|---|---|---|
| Example | Substrate | Index | E9D | (%) | (%) | (\acute{ }/min) |
| 1 | Soda Lime | 1.869 | −0.8 | 20.9 | 20.1 | 4042.0 |
| 2 | Soda Lime | 1.936 | −1.1 | 25.2 | 17.0 | 3157.0 |
| 3 | Soda Lime | 1.876 | −14.9 | 2.9 | 32.7 | 1632.0 |
| 4 | Soda Lime | 1.799 | −13.6 | 0.6 | 31.0 | 6400.0 |
| 5 | Soda Lime | 1.447 | −0.1 | N/A | N/A | N/A |
| 6 | Soda Lime | N/A | N/A | N/A | N/A | N/A |
| 7 | Corning | N/A | N/A | N/A | N/A | N/A |
| 8 | Silicon | N/A | N/A | N/A | N/A | N/A |

### Example 1

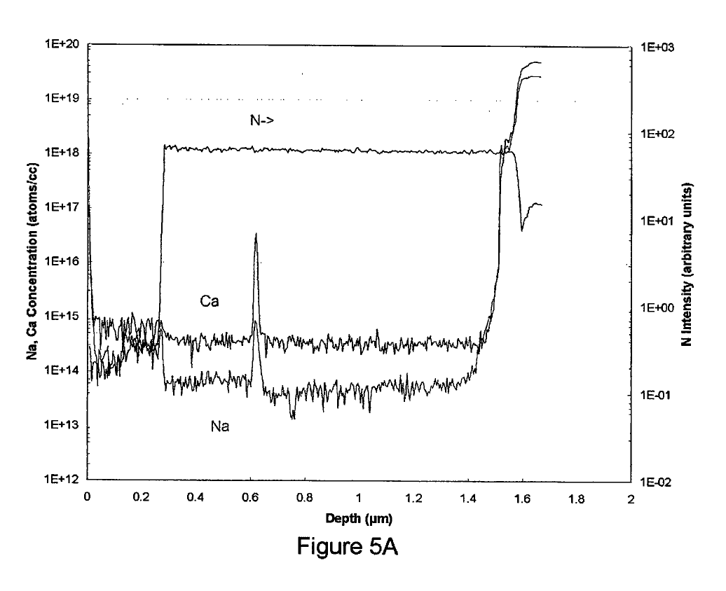

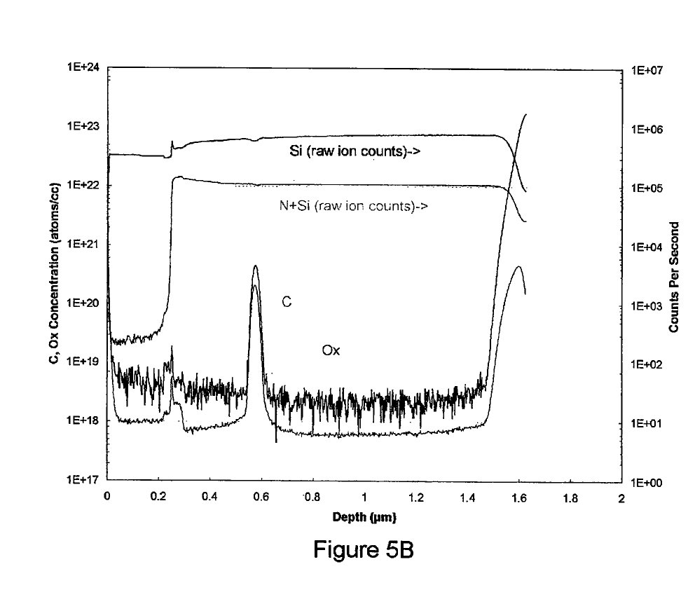

A TFT was deposited over a soda lime glass substrate disposed on a susceptor maintained at a temperature of 200 degrees Celsius. A 1.0 micron silicon rich silicon nitride barrier layer was deposited over the soda lime glass substrate prior to depositing the TFT. FIGS. 5A and 5B are secondary ion mass spectrometry charts showing the sodium and carbon density as measured in the middle of the barrier layer. The refractive index is below 1.900, and the wet etch rate is above 4000 Angstroms/min. The sodium density is still within the acceptable range and only 2 orders of magnitude greater than a non-alkali glass substrate. When a barrier layer is present, the sodium concentration may remain below about 1×10¹⁵ atoms/cc between the amorphous silicon layer and the substrate as measured by secondary ion mass spectrometry. Additionally, the carbon concentration may remain below about 1×10¹⁹ atoms/cc for most of the distance between the amorphous silicon layer and the substrate as measured by secondary ion mass spectrometry.

### Example 2

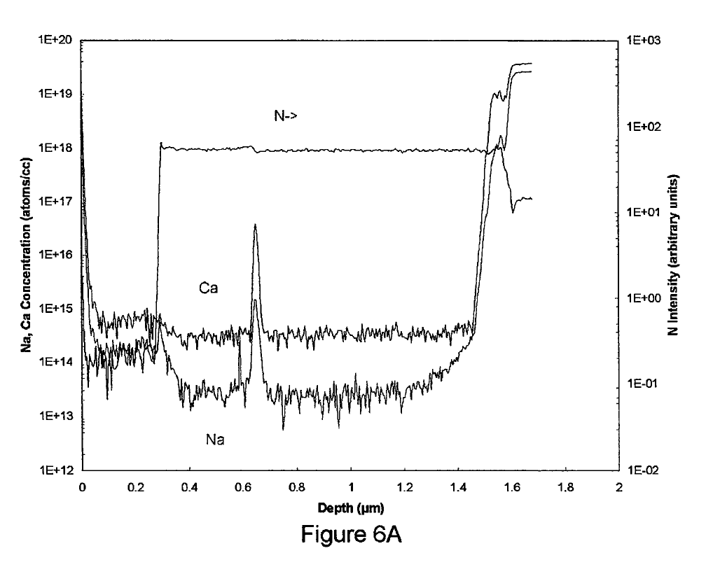

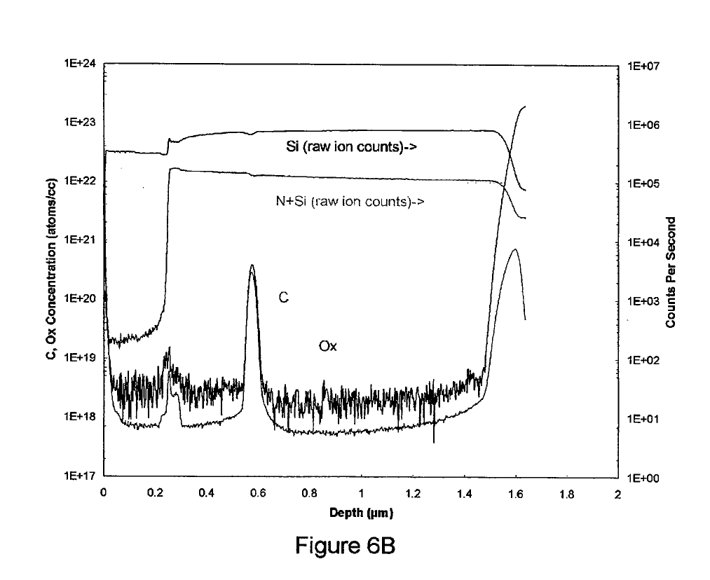

A TFT was deposited over a soda lime glass substrate disposed on a susceptor maintained at a temperature of 200 degrees Celsius. A 1.0 micron silicon rich silicon nitride barrier layer was deposited over the soda lime glass substrate prior to depositing the TFT. FIGS. 6A and 6B are secondary ion mass spectrometry charts showing the sodium and carbon density as measured in the middle of the barrier layer. The refractive index is above 1.900, and the wet etch rate is below 3200 Angstroms/min. The sodium density is well within the acceptable range and only 1 order of magnitude greater than a non-alkali glass substrate. When a barrier layer is present, the sodium concentration may remain below about 1×10¹⁵ atoms/cc between the amorphous silicon layer and the substrate as measured by secondary ion mass spectrometry. Additionally, the carbon concentration may remain below about 1×10¹⁹ atoms/cc for most of the distance between the amorphous silicon layer and the substrate as measured by secondary ion mass spectrometry.

### Example 3

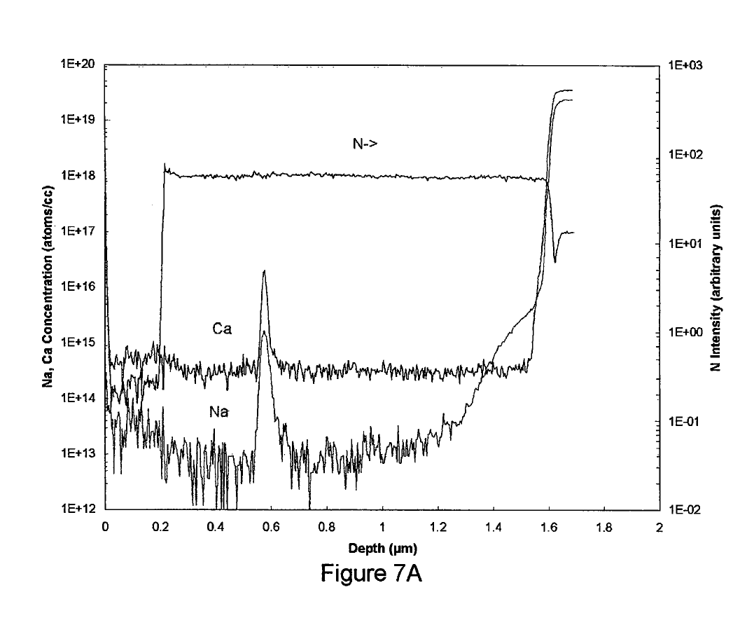

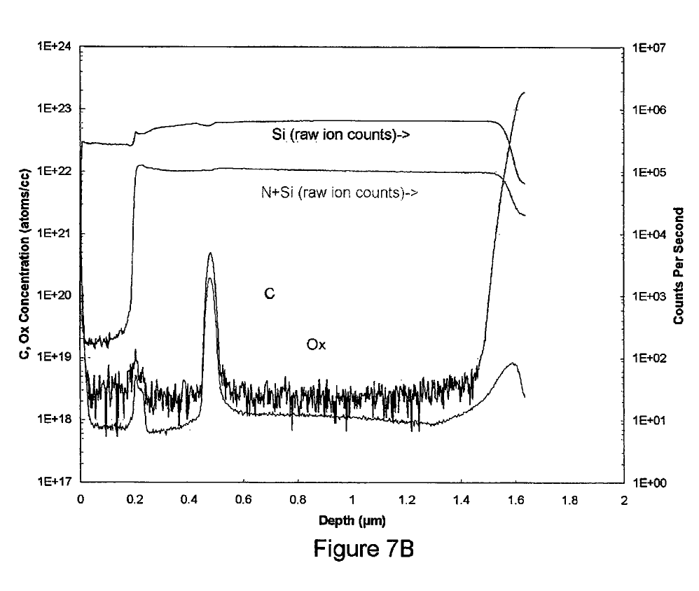

A TFT was deposited over a soda lime glass substrate disposed on a susceptor maintained at a temperature of 200 degrees Celsius. A 1.0 micron silicon rich silicon nitride barrier layer was deposited over the soda lime glass substrate prior to depositing the TFT. FIGS. 7A and 7B are secondary ion mass spectrometry charts showing the sodium and carbon density as measured in the middle of the barrier layer. The refractive index is below 1.900. However, the wet etch rate is low. The sodium density is still within the acceptable range and only 2 orders of magnitude greater than a non-alkali glass substrate, but combined with the carbon density being an order of magnitude above a non-alkali glass substrate, the TFT is approaching the limit of acceptability. When a barrier layer is present, the sodium concentration may remain below about 1×10¹⁵ atoms/cc between the amorphous silicon layer and the substrate as measured by secondary ion mass spectrometry. Additionally, the carbon concentration may remain below about 1×10¹⁹ atoms/cc for most of the distance between the amorphous silicon layer and the substrate as measured by secondary ion mass spectrometry.

### Example 4

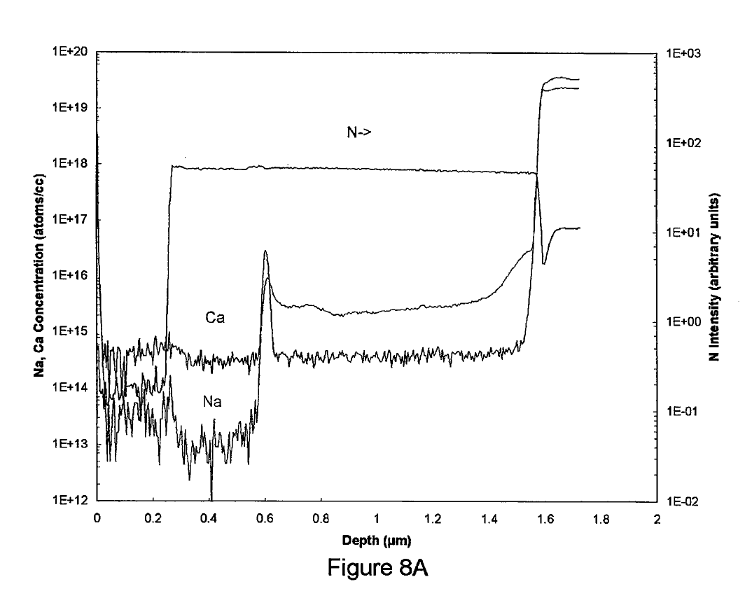

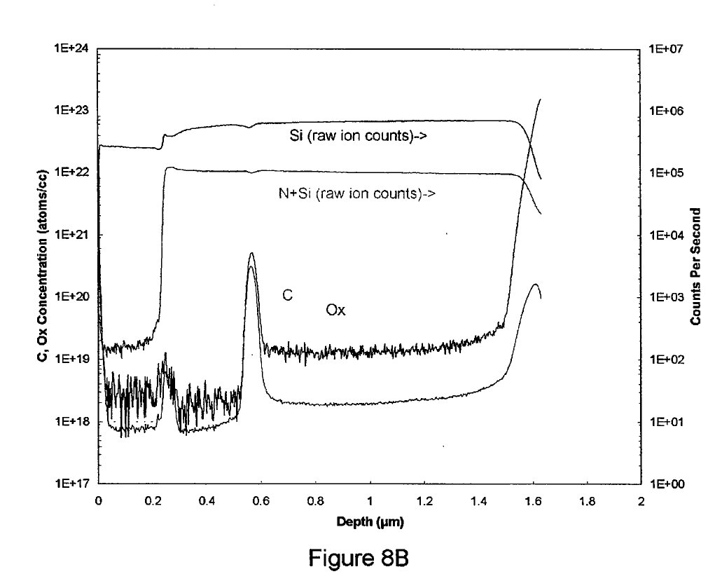

A TFT was deposited over a soda lime glass substrate disposed on a susceptor maintained at a temperature of 200 degrees Celsius. A 1.0 micron silicon rich silicon nitride barrier layer was deposited over the soda lime glass substrate prior to depositing the TFT. FIGS. 8A and 8B are secondary ion mass spectrometry charts showing the sodium and carbon density as measured in the middle of the barrier layer. The refractive index is below 1.900, and the wet etch rate is above 6000 Angstroms/min. The sodium density is still within the acceptable range and at 3 orders of magnitude greater than a non-alkali glass substrate, but combined with the carbon density being an order of magnitude above a non-alkali glass substrate, the TFT is at the limit of acceptability. When a barrier layer is present, the sodium concentration may remain below about 1×10¹⁵ atoms/cc between the amorphous silicon layer and the substrate as measured by secondary ion mass spectrometry. Additionally, the carbon concentration may remain below about 1×10¹⁹ atoms/cc for most of the distance between the amorphous silicon layer and the substrate as measured by secondary ion mass spectrometry.

### Comparison Example 1

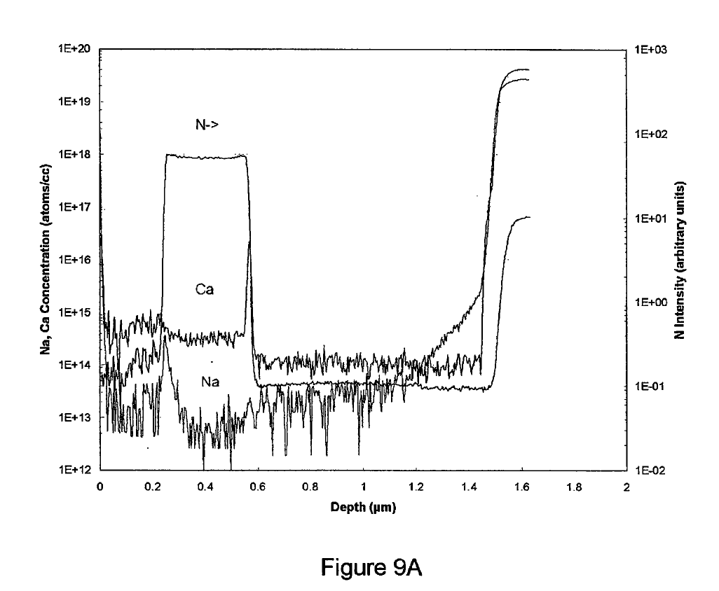

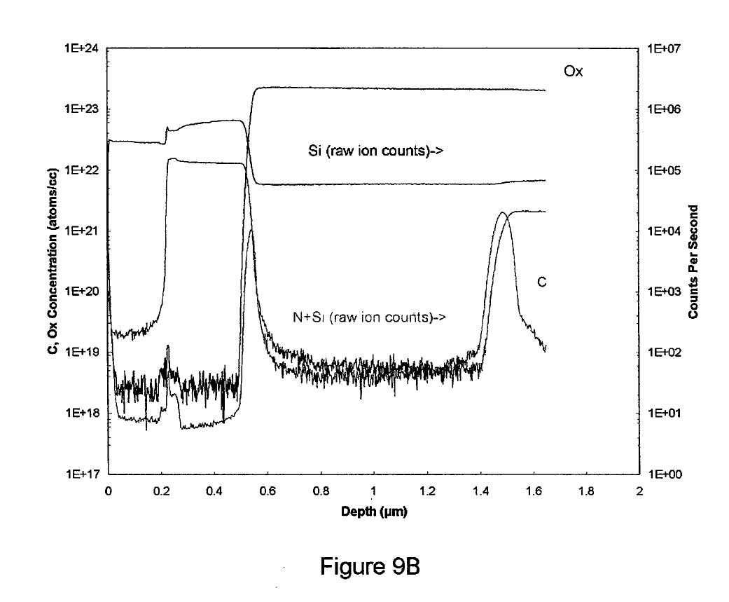

A TFT was deposited over a soda lime glass substrate disposed on a susceptor maintained at a temperature of 200 degrees Celsius. A 1.0 micron silicon oxide barrier layer was deposited over the soda lime glass substrate prior to depositing the TFT. FIGS. 9A and 9B are secondary ion mass spectrometry charts showing the sodium and carbon density as measured in the middle of the barrier layer. The refractive index is well below 1.900, and the wet etch rate is above 3500 Angstroms/min. The sodium density is still within the acceptable range and at 2 orders of magnitude greater than a non-alkali glass substrate, but the carbon density being more than an order of magnitude above a non-alkali glass substrate, the TFT is beyond the limit of acceptability.

### Comparison Example 2

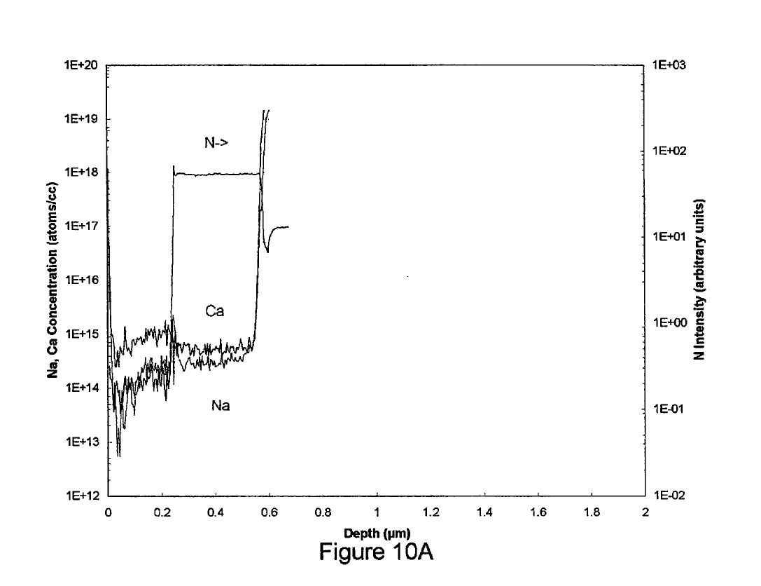

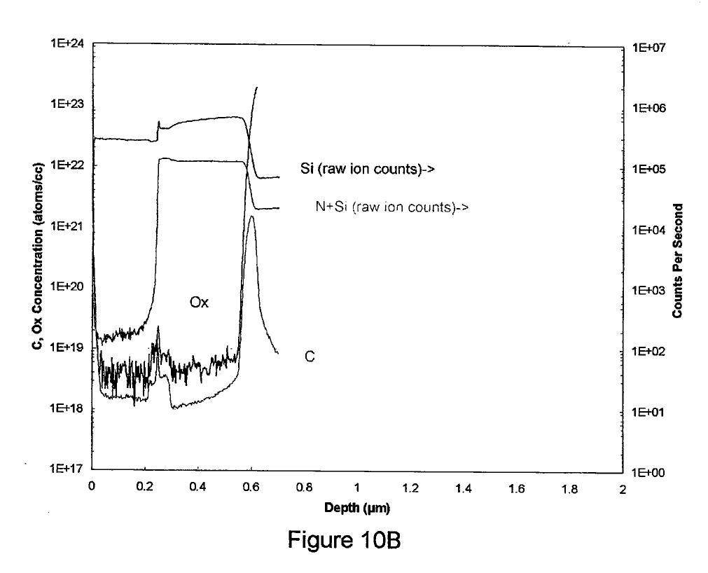

A TFT was deposited over a soda lime glass substrate disposed on a susceptor maintained at a temperature of 200 degrees Celsius. No barrier layer was deposited over the soda lime glass substrate prior to depositing the TFT. FIGS. 10A and 10B are secondary ion mass spectrometry charts showing the sodium and carbon density as measured in the middle of the gate dielectric layer. The refractive index is so low that when coupled with the sodium density at 2 orders of magnitude greater than a non-alkali glass substrate and the carbon density being more than an order of magnitude above a non-alkali glass substrate, the TFT is beyond the limit of acceptability.

### Comparison Example 3

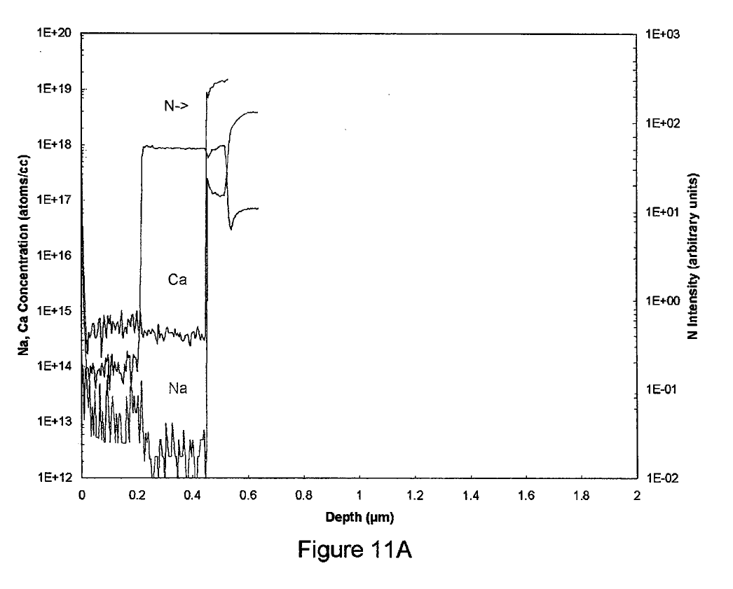

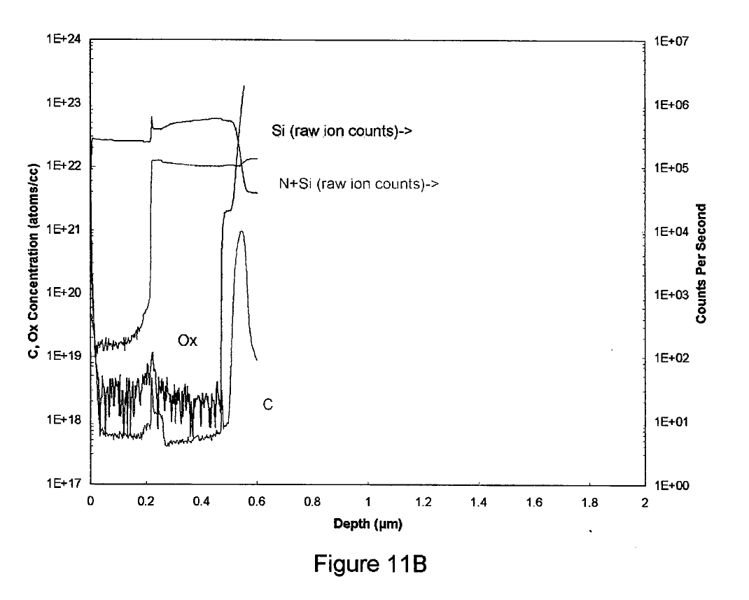

Comparison Example 3 is the control example. A TFT was deposited over a Corning glass substrate disposed on a susceptor maintained at a temperature of 200 degrees Celsius. No barrier layer was deposited over the Corning glass substrate prior to depositing the TFT. FIGS. 11A and 11B are secondary ion mass spectrometry charts showing the sodium and carbon density as measured in the middle of the gate dielectric layer. The sodium density and carbon density are well within the acceptable range.

### Comparison Example 4

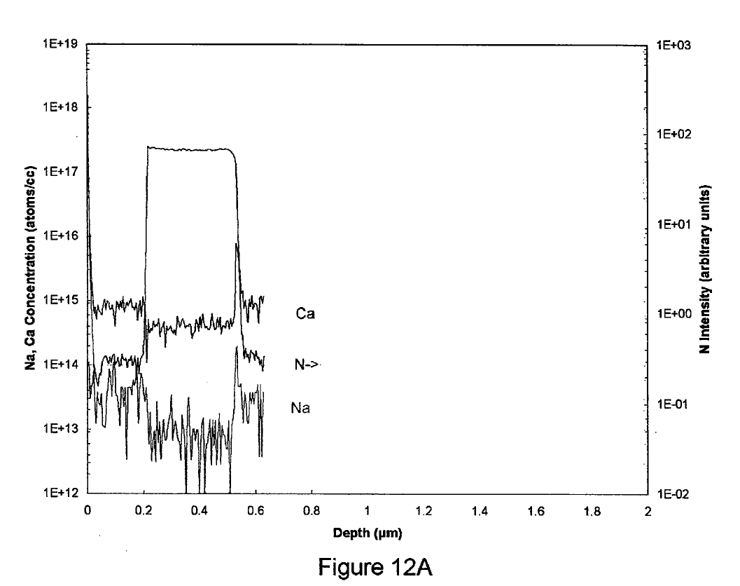

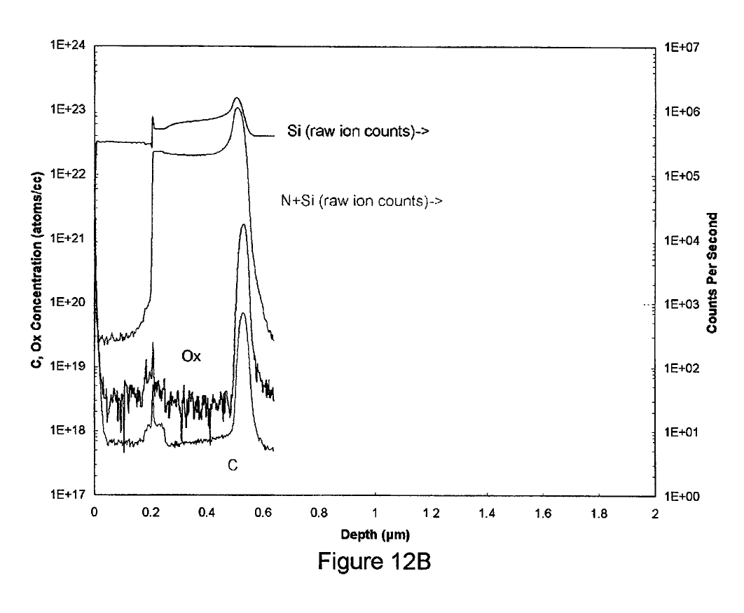

A TFT was deposited over a silicon wafer substrate disposed on a susceptor maintained at a temperature of 200 degrees Celsius. No barrier layer was deposited over the silicon wafer substrate prior to depositing the TFT. FIGS. 12A and 12B are secondary ion mass spectrometry charts showing the sodium and carbon density as measured in the middle of the gate dielectric layer. The refractive index is so low that when coupled with the sodium density at 1 order of magnitude greater than a non-alkali glass substrate and the carbon density being more than an order of magnitude above a non-alkali glass substrate, the TFT is beyond the limit of acceptability.

TABLE IV

| | | | Barrier layer |
|---|---|---|---|
| | | Barrier | thickness |
| Example | Substrate | layer | (Angstroms) |
| 5 | Kapton ™ | SiN | 4000 |
| 6 | Kapton ™ | N/A | N/A |
| 7 | Kapton ™ | N/A | N/A |
| Comparison 5 | Silicon | SiO | 10000 |
| | wafer | | |

### Example 5

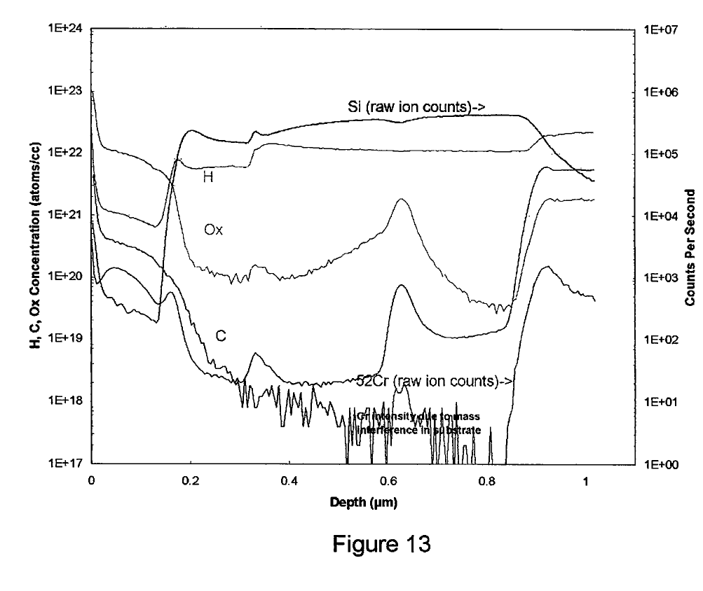

A TFT was deposited over a Kapton™ substrate disposed on a susceptor maintained at a temperature of 200 degrees Celsius. A 4,000 Angstrom silicon rich silicon nitride barrier layer was deposited over the Kapton™ substrate prior to depositing the TFT. FIG. 13 is a secondary ion mass spectrometry chart showing the carbon density as measured in the middle of the barrier layer. When a barrier layer is present, the carbon concentration may remain below about 1×10²⁰ atoms/cc between the amorphous silicon layer and the substrate as measured by secondary ion mass spectrometry.

### Example 6

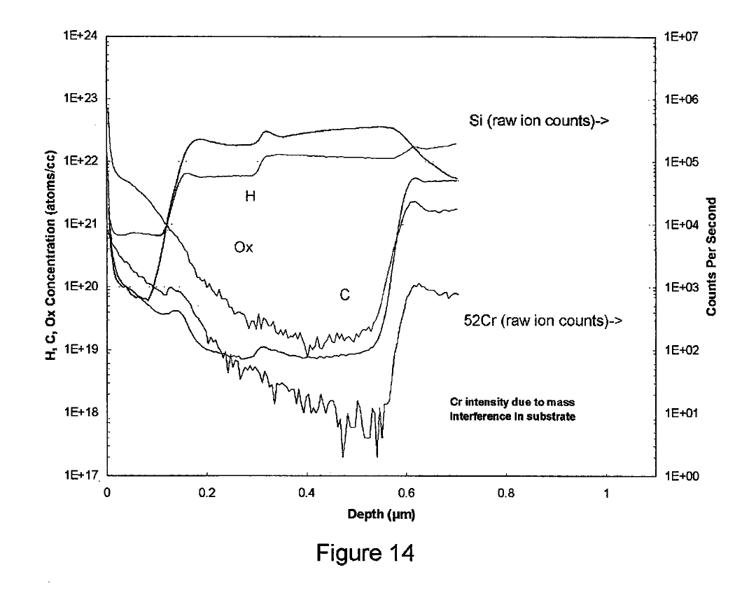

A TFT was deposited over a Kapton™ substrate disposed on a susceptor maintained at a temperature of 200 degrees Celsius. No barrier layer was deposited over the Kapton™ substrate prior to depositing the TFT. FIG. 14 is a secondary ion mass spectrometry chart showing the carbon density as measured in the middle of the gate dielectric layer. When a barrier layer is present, the carbon concentration may remain below about 1×10²⁰ atoms/cc between the amorphous silicon layer and the substrate as measured by secondary ion mass spectrometry.

### Example 7

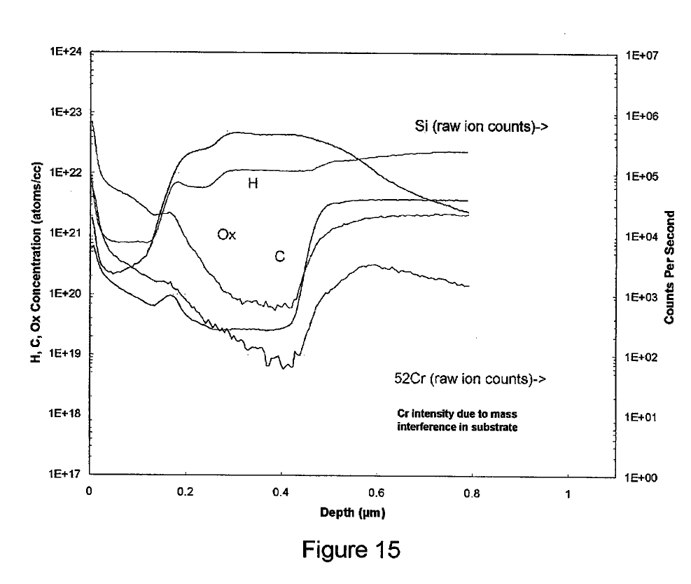

A TFT was deposited over a Kapton™ substrate disposed on a susceptor maintained at a temperature of 200 degrees Celsius. No barrier layer was deposited over the Kapton™ substrate prior to depositing the TFT. FIG. 15 is a secondary ion mass spectrometry chart showing the carbon density as measured in the middle of the gate dielectric layer. When a barrier layer is present, the carbon concentration may remain below about 1×10²⁰ atoms/cc between the amorphous silicon layer and the substrate as measured by secondary ion mass spectrometry.

### Comparison Example 5

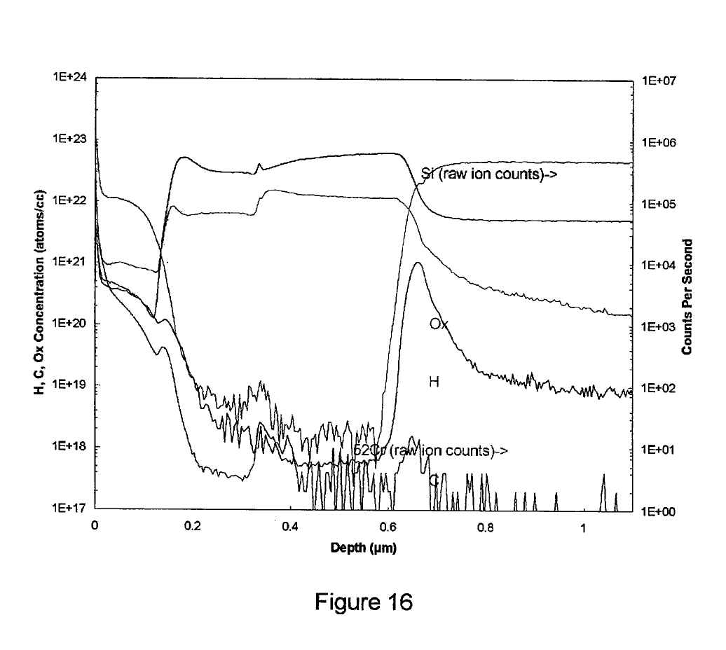

A TFT was deposited over a silicon wafer substrate disposed on a susceptor maintained at a temperature of 200 degrees Celsius. A 10,000 Angstrom thick silicon oxide barrier layer was deposited over the silicon wafer substrate prior to depositing the TFT. FIG. 16 is a secondary ion mass spectrometry chart showing the carbon density as measured in the middle of the barrier layer.

By utilizing a silicon rich barrier layer over a soda lime glass substrate or a polyimide containing substrate, sodium and carbon diffusion may be reduced. Thus, lower cost substrates may be used without fear of contamination. Therefore, TFTs may be manufactured at a lower cost. No additional layer is present or necessary between the silicon rich barrier layer and the gate dielectric. Additionally, no additional layer is present or necessary between the substrate and the silicon rich barrier layer.

While the foregoing is directed to embodiments of the present invention, other and further embodiments of the invention may be devised without departing from the basic scope thereof, and the scope thereof is determined by the claims that follow.

1. A thin film transistor, comprising:
a soda lime glass substrate or a substrate comprising a polyimide; and
a silicon rich silicon nitride barrier layer disposed over the substrate, the barrier layer having a silicon:nitrogen ratio greater than 0.83:1.0.

2. The thin film transistor of claim 1, wherein the barrier layer has a SiH content between about 18 atomic percent and about 21 atomic percent.

3. The thin film transistor of claim 1, wherein the barrier layer has a refractive index equal to or greater than about 1.900.

4. The thin film transistor of claim 3, wherein the refractive index is between about 1.920 and about 1.940.

5. The thin film transistor of claim 1, further comprising a second barrier layer disposed over the silicon rich silicon nitride barrier layer.

6. The thin film transistor of claim 1, wherein the barrier layer has a thickness between about 0.75 microns to about 1.25 microns.

7. The thin film transistor of claim 1, the thin film transistor has a subthreshold swing between about 0.9 V/dec to about 1.5 V/dec.

8. A thin film transistor formation method, comprising:
depositing a silicon rich silicon nitride barrier layer over a soda lime glass substrate, the barrier layer having a silicon:nitrogen ratio greater than 0.83:1.0;
depositing a metal gate layer over the barrier layer;
depositing a gate dielectric layer over the metal gate layer;
depositing an active layer over the gate dielectric layer;
depositing a source-drain region over the active layer; and
depositing a passivation layer over the source-drain region.

9. The method of claim 8, wherein the barrier layer is deposited by plasma enhanced chemical vapor deposition.

10. The method of claim 8, wherein the barrier layer is deposited by introducing a silicon precursor gas, a nitrogen precursor gas, nitrogen gas, and hydrogen gas.

11. The method of claim 10, wherein the silicon precursor gas comprises silane.

12. The method of claim 10, wherein the nitrogen precursor gas comprises ammonia.

13. The method of claim 8, wherein the barrier layer has a SiH content between about 18 atomic percent and about 21 atomic percent.

14. The method of claim 8, wherein the barrier layer has a refractive index equal to or greater than about 1.900.

15. A thin film transistor formation method, comprising:
depositing a silicon rich silicon nitride barrier layer over a substrate comprising a polyimide, the barrier layer having a silicon:nitrogen ratio greater than 0.83:1.0;
depositing a metal gate layer over the barrier layer;
depositing a gate dielectric layer over the metal gate layer;
depositing an active layer over the gate dielectric layer;
depositing a source-drain region over the active layer; and
depositing a passivation layer over the source-drain region.

16. The method of claim 15, wherein the barrier layer is deposited by plasma enhanced chemical vapor deposition.

17. The method of claim 15, wherein the barrier layer is deposited by introducing a silicon precursor gas, a nitrogen precursor gas, nitrogen gas, and hydrogen gas.

18. The method of claim 17, wherein the silicon precursor gas comprises silane.

19. The method of claim 17, wherein the nitrogen precursor gas comprises ammonia.

20. The method of claim 15, wherein the barrier layer is deposited at a substrate temperature between about 180 degrees Celsius and about 205 degrees Celsius.
